(19) United States
(12) Patent Application Publication
(10) Pub. No.: US 2014/0002145 A1
(43) Pub. Date: Jan. 2, 2014

(54) DRIVING CIRCUIT FOR A TRANSISTOR

(71) Applicants: Anton Mauder, Kolbermoor (DE); Armin Willmeroth, Augsburg (DE)

(72) Inventors: Anton Mauder, Kolbermoor (DE); Armin Willmeroth, Augsburg (DE)

(73) Assignee: INFINEON TECHNOLOGIES AUSTRIA AG, Villach (AT)

(21) Appl. No.: 13/534,003

(22) Filed: Jun. 27, 2012

(51) Int. Cl. H03K 3/015

(52) U.S. Cl. 327/109

(57) ABSTRACT

In various embodiments, a driving circuit for a transistor is provided. The driving circuit may include a transistor including a control terminal; a capacitance; a first switch and a power source, wherein the first switch may be coupled between the power source and a first terminal of the capacitance; a second switch and an inductance which may be coupled in series between the first terminal of the capacitance and the control terminal of the transistor.

### TECHNICAL FIELD

Various embodiments relate to a driving circuit for a transistor.

### BACKGROUND

One aim of new developments in power semiconductor switches is to obtain components with as high blocking voltages as possible which nevertheless can offer a low on-state resistance. For this purpose, EGFETs (extended gate FETs) have been developed in which in addition to the gate so-called drift control zones are provided in the transistor between the source and the drain in order to provide reduced on-state resistance. However, high control currents are needed for driving the drift control zones in order to achieve a low on-state resistance, i.e. for introducing charges into the drift control zones when the EGFET is to be rendered into a conducting state and depleting the drift control zones from charges, when the EGFET is to be rendered into a non-conducting state.

### SUMMARY

In various embodiments, a driving circuit for a transistor is provided. The driving circuit may include a transistor including a control terminal; a capacitance; a first switch and a power source, wherein the first switch may be coupled between the power source and a first terminal of the capacitance; a second switch and an inductance which may be coupled in series between the first terminal of the capacitance and the control terminal of the transistor.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows an implementation of a driving circuit for a transistor according to various embodiments;

FIG. 2 shows a further implementation of a driving circuit for a transistor according to various embodiments;

FIG. 3 shows yet another implementation of a driving circuit for a transistor according to various embodiments;

FIG. 4 shows yet another implementation of a driving circuit for a transistor according to various embodiments;

FIG. 5A and FIG. 5B show an exemplary gate voltage and an exemplary drain voltage of the transistor in a driving circuit for a transistor according to various embodiments during switching;

FIG. 6 shows an exemplary switching method for the transistor in a driving circuit for the transistor according to various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

One approach in order to solve the problem of high control powers (for example high control currents) needed for driving the drift control regions in EGFETs led to the development of TEDFETs (trench extended drain FETs). A TEDFET device has a similar structure to an EGFET device as it also includes drift control regions which are arranged laterally adjacent to a drift region which may extend from the source region arranged at one surface of the substrate towards the drain region arranged on the opposite surface of the substrate. The drift control region(s) is (are) separated from the drift region by a dielectric layer which is also referred to as accumulation dielectric or accumulation oxide (AOX). When a TEDFET is driven into conducting state, the drift control regions may be used for controlling an accumulation channel which is formed alongside the accumulation dielectric on the side of the drift region. The accumulation channel may be seen as a region characterized by a locally increased charge carrier density. A prerequisite for the formation of the accumulation channel is a potential difference between the drift control regions and the drift region. The presence of the accumulation channel in the drift region induced by charged drift control regions may result in a reduced on-state resistance of the power semiconductor component.

In TEDFETs, the charges which are provided to the drift control regions in order to reach a low on-state resistance are stored in capacitors which are electrically coupled between the drift control region and the source region. In presently available TEDFET devices, those capacitors are at least partially or fully provided in the drift control region, as it is the case in TEDFET devices currently under development, in order to avoid the necessity of conducting high currents over contacts and in order to avoid parasitic effects, for example due to the presence of stray or distributed inductances. However, the storing of charges based on integrated capacitors may be very space consuming—for example, 50% of the surface of the chip may be needed for the drift control regions. Furthermore, the voltage increase in the capacitor during a transition from the on-state into the off-state of a respective TEDFET may be seen as disadvantageous. The voltage increase in the capacitor is caused by the following effect. In the on-state of the TEDFET the storing capacitor, i.e. the capacitor used for storing the charges which are introduced and withdrawn from the drift control regions, and there accumulation capacitor, i.e. the capacitor which is formed across the accumulation dielectric, are coupled in parallel. In the off-state, in contrast, the accumulation capacitor is not present as no charges are present in the drift control region which may induce a corresponding charge in the drift region separated therefrom by the accumulation dielectric. In the off-state, the semiconductor volume in the drift region and in the drift control region becomes an isolator due to the spread of the depletion region while the charge needs to be conserved. Therefore, all of the charge must be confined in the storing capacitor. The storing capacitor is arranged in the so-called head of the drift control region, i.e. in the region of the drift control region which is located at the height of the body of the TEDFET, or it is electrically connected thereto. Consequently, a relatively high voltage drop occurs between the upper regions of the drift control region and the drift region in the off-state of the transistor. This relatively high voltage drop may reduce the blocking capability of the drift region with respect to voltages being applied across the transistor, i.e. between the source and the drain thereof. Tolerable voltages between the upper regions of the drift control regions and the drift region in the off-state of the transistor which do not result in a drop of the blocking capability of the TEDFET are lower than the possible voltages which in principle could be endured by the accumulation dielectric. For example, for an accumulation dielectric layer with a thickness of 100 nm the voltage across that layer should not exceed 23V if damage is to be prevented. Due to a higher voltage building up across the accumulation dielectric in the off-state of the transistor, in fast switching applications a voltage of approximately up to 14V may be applied to the drift control region in the on-state of the transistor which is then increased to up to 21V in the off-state of the transistor, even though the accumulation dielectric may be able to sustain a state in which a voltage of, for example, 23V is permanently applied across the accumulation dielectric. In consequence, the possibility of further reducing the on-state resistance by approximately 40% in otherwise the same devices with respect to their geometry, when the drift control region voltage in the on-state of the TEDFET has to be capped at approximately 14V instead of the potentially feasible 23V.

In various embodiments, a driving circuit for a transistor is provided which may provide an intelligent and resonant driving for a transistor, for example for an EGFET or a TEDFET. The driving circuit may solve the problem of a too high control power needed for the power transistor, for example an EGFET, and the problem of space requirement for capacitors in the drift control region. It may further solve the problem of the reduced blocking voltage of the transistor when a high voltage is applied to the drift control region and it may also reduce the on-state resistance of the transistor by 40% in comparison to a transistor with a drift region, a drift control region and an accumulation dielectric of the same dimensions.

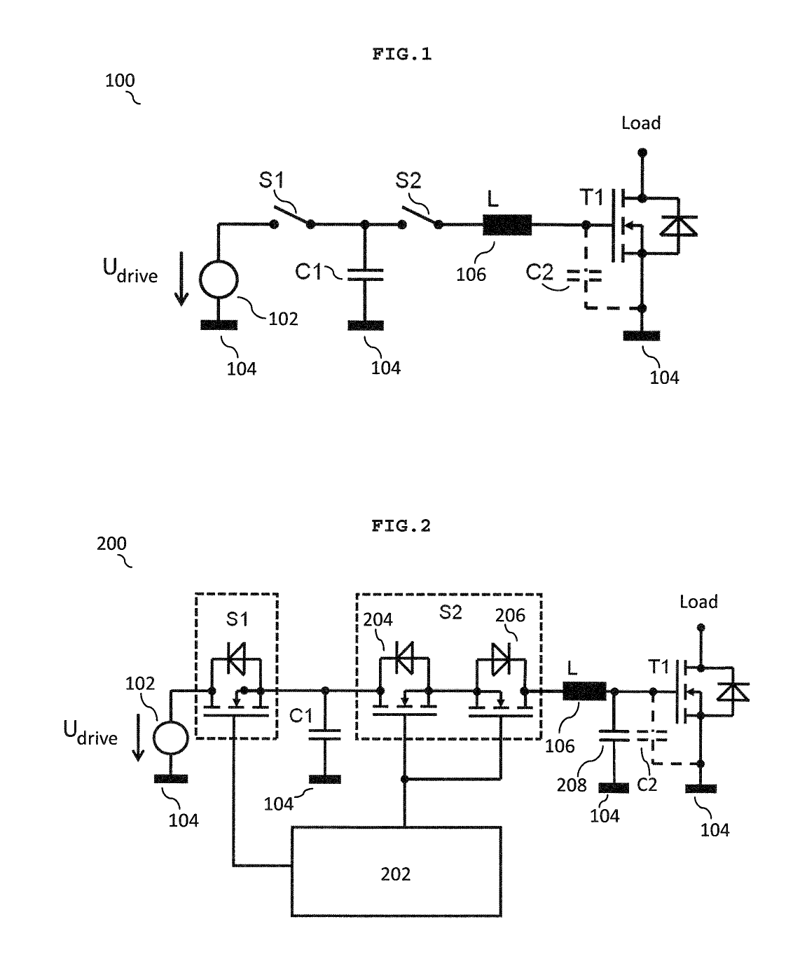

In FIG. 1 a driving circuit 100 for a transistor according to various embodiments is shown. The driving circuit 100 may be used to control the operation of a transistor T1 which may, for example, be an EGFET. However, the driving circuit 100 may be also used in order to control the operation of a TEDFET or any other transistor which may require a substantial amount of electrical charge to be provided to its control regions in its conducting state. A driving voltage U_{drive} from a power source 102 may be provided to a control terminal of the load transistor T1 via a series arrangement including a first switch S1, a second switch S2 and an inductance 106 (also labelled L).

The control terminal of the transistor T1 may include control regions of the transistor such as at least one gate region and at least one drift control region. The at least one drift control region may extend between the source and the drain of the load transistor T1. For example, one drift control region may be arranged adjacent to the drift region, for example at its left side, and a further drift control region may be arranged adjacent to the drift region, for example at its right side. Both the drift region and the drift control regions may extend vertically alongside one another between the source and the drain of the transistor T1. The drift control regions may be used to further reduce the on-state resistance of the load transistor by the mechanisms described above. The gate region and the at least one drift control region of the transistor T1 may be coupled in parallel to its control terminal or they maybe be formed from the same structure, for example a continuous polycrystalline silicon layer or a region surrounded by a dielectric layer, wherein one part of that structure fulfils the functionality of a classical gate and the other part(s) of that structure fulfil(s) the functionality of drift control region(s). However, this is only an example. The gate region and the at least one drift control region may also be driven by different, for example synchronized signals. The load transistor T1 further includes the drain terminal, to which a load may be connected and the source terminal, which may be connected to a reference potential 104, for example the ground potential. The transistor body diode between the source terminal and the drain terminal of the transistor T1 is also displayed. The transistor T1 includes a second capacitance C2, which is coupled between the control terminal of the transistor T1 and its drain terminal and may represent a capacitance which is inherently present (and thus shown dashed) in the load transistor T1. The second capacitance C2 may thus be equivalent to an internal capacitance may represent the gate capacitance and the drift control region capacitance which are coupled in parallel to the control terminal of the transistor T1. During or in the on-state of the transistor T1, the value of the second capacitance C2 may be dominated by the capacitance of the drift control region. The drift control region capacitance may be seen as a variable capacitor which, depending on the state of the load transistor T1, i.e. whether it is in conducting or non-conducting state, may provide a larger or a smaller contribution to the second capacitance C2.

The driving circuit 100 according to various embodiments includes further includes a first capacitance C1. One side or terminal of the first capacitance C1 is coupled to the electrical path between the first switch S1 and the second switch S2, the other side or terminal of the first capacitance C1 is coupled to the reference potential 104. The power source 102 may be configured as a constant voltage source (DC voltage source). The first switch S1 and the second switch S2 are used for switching on (i.e. rendering into a conducting state) and switching off (i.e. rendering into a non-conducting state) the load transistor T1. In the following, the operation of the driving circuit 100 according to various embodiments will be described in more detail.

With the driving circuit 100 according to various embodiments it is possible to store charges in the first capacitance C1 which may be provided to the control terminal, for example to the gate region and the at least one drift control region of the load transistor T1, in its on-state. Charges stored in the first capacitance C1 may oscillate back and forth between the first capacitance C1 and the second capacitance C2 provided in the load transistor T1 by the help of the inductance 106 and depending on the state of the second switch S2 and the state of the first capacitance C1, i.e. whether it is charged or not. When the first capacitance C1 is charged and the second switch S2 is closed (i.e. rendered conducting), the energy stored in the electric field of the first capacitance C1 may be transferred to the inductance 106 and be stored therein in the form of a magnetic field while the second capacitance C2 is simultaneously charged. When the voltage of the first capacitance C1 falls below the voltage of the second capacitance, the energy stored in the inductance 106 is released and drives a current which continues to charge the second capacitance C2. In other words, the inductance 106 may be seen as an electrical flywheel which allows for an efficient transfer of charges from the first capacitance C1 to the second capacitance C2 of the load transistor T1.

The first capacitance C1 and the second capacitance C2 may, in one embodiment, have substantially equal capacitance values. As already mentioned, the capacitance value of the second capacitance C2 tends to be larger when the transistor is in conducting state (i.e. switched on) in comparison to its capacitance value when the transistor T1 is in non-conducting state (i.e. switched off on). With regard to this effect, the capacitance value of the second capacitance C2 may refer to the capacitance value thereof in the on-state of the load transistor T1.

Before the load transistor T1 is switched on for the first time, the first capacitance C1 is charged until its voltage reaches the driving voltage U_{drive} provided by the power source 102. During this phase, the first switch S1 may be closed (i.e. in its conducting state) while the second switch S2 may be open (i.e. in its non-conducting state). When the charging process of the first capacitance C1 has completed, the first switch S1 may be opened again, whereby the power source 102 is disconnected from the first capacitance C1.

When the load transistor T1 is to be switched on, the second switch S2 is closed and a driving current may flow from the first capacitance C1 to the second capacitance C2 of the transistor T1 via the second switch S2 and the inductance 106. Assuming negligible losses which, for example, may be caused by a resistance of the inductance 106 and/or by the series resistance of the second switch S2 and/or by the series resistance of the first capacitance C1 and the second capacitance C2, the second capacitance C2 is charged up to a voltage of the first capacitance C1 before the second switched S2 has been closed. In other words, in this exemplary scenario of the capacitance value of the first capacitance C1 being substantially equal to the capacitance value of the second capacitance C2, the state of the capacitance C1 is substantially “copied” onto the second capacitance C2 of the transistor T1. As soon as this process is finished, the second switch S2 is opened in order to prevent a flow of charges back from the second capacitance C1 back towards the first capacitance C1. The charges transferred to the control terminal and thereby to the control regions remain located therein, for example in the gate region and the drift control regions, and the load transistor T1 is in on-state.

The time during which the transistor T1 is in conducting state may be controlled by the switch-off time of the second switch S2. That is, the transistor T1 will remain switched on for as long as the second switch S2 is kept opened such that the charges that have been transferred to the control regions (for example to the gate region and the drift control regions of the transistor T1) cannot be discharged therefrom (neglecting leakage currents). If the load transistor T1 is to be switched off, the second switch S2 is closed which will cause the charges to flow from the second capacitance C2 via the inductance 106 into the first capacitance C1. At the end of the discharge process of the first capacitance C1 the second switch S2 may be opened again such that the load transistor T1 may remain switched off for a desired amount of time. During the time in which the load transistor T1 is in off-state, the first switch S1 may be closed and the first capacitance C1 may be charged to a voltage which is equal to the driving voltage U_{drive} provided by the power source 102. This recharging process may be used, for example, in order to compensate for (ohmic) losses, for example leakage current losses during the switching process and/or losses in the domain of the transistor T1 during the time it was in on-state. The first switch S1 may need to be opened again before or at the latest when the next switch-on of the transistor T1 takes place, i.e. when the second switch S2 is opened again.

The magnitude of the current flowing from the first capacitance C1 (or from the power source 102 when the transistor T1 is to be switched on and the first capacitance C1 is not yet charged) or the rate at which the current charging the second capacitance C2 is increasing is defined by the inductance 106 which may be seen to act as a current limiter. With increasing inductance values of the inductance 106, the charging process and the discharging process of the second capacitance C2 consumes more time such that timing constraints with regard to the second switch S2 become less critical. In other words, the precise choice of the point in time when the second switch S2 is to be closed or opened may not be the most critical parameter defining the point in time when the transistor T1 is fully operational (for example fully/completely conducting or fully/completely non-conducting) as the switch-on process and the switch-off process of the transistor T1 may be dominated by the inductance 106 which may limit both the charging current and the discharging current. By choosing an appropriate inductance for the inductance 106, i.e. by adjusting the inductive reactance of the inductance 106, the switching characteristic of the load transistor T1 may be adjusted without the necessity of charging the gate and the drift control regions of the load transistor T1 via the commonly used but lossy gate resistance. When the ohmic resistance of the conducting paths is neglected, the driving circuit for a transistor 100 according to various embodiments enables substantially lossless driving of the load transistor T1. This aspect may prove to be increasingly advantageous over the conventional method of using a gate resistance as the input capacitance of the load transistor becomes larger. Under the assumption of the first capacitance C1 and the second capacitance C2 having approximately equal capacitance values, the switch-on time tₒₙ (and to a first approximation also the switch-off time) of the load transistor T1, which may be seen to be equivalent to the time the second switch S2 needs to remain closed, amounts to half the oscillating time period of the oscillator circuit formed by the inductance 106 and the first capacitance C1,

tₒₙ=π\sqrt{LC1}

It is to be noted that while the oscillating time period determines the transition process between the on-state and the off-state (in both directions) of the load transistor T1, the actual time during which the transistor T1 remains switched on or switched off is not affected thereby, as it is independent from the oscillating time period and is basically defined by the time during which the second switch S2 remains open. However, during fast switching processes in combination with low source-to-drain currents through the load transistor T1, for example, the switching off process may be delayed due to internal capacitances within the load transistor T1 still being discharged, such that a load current is still flowing through the transistor T1 while the gate region is already “switched off”.

The driving circuit for a transistor according to various embodiments enables driving components such as transistors at high frequencies, even when they require a high control region charge (for example including the gate region and at least one drift control region), such as the EGFET or the TEDFET. In other words, the driving circuit for a transistor according to various embodiments may be configured to store or buffer and reuse the charges from the control regions of the transistor, such that a power efficient switching of transistors requiring a high control region charge is possible at high frequencies. The driving circuit for a transistor according to various embodiments enables may include an external capacitance, an inductance and two switches, wherein the switches are used to connect the external capacitance either to a power source or via the inductance to the control region of the transistor, wherein in the case of the external capacitance being connected to the control region of the transistor via the inductance, after half the oscillating time period which is determined by the external capacitance and the inductance the external capacitance is disconnected from the control region of the transistor by opening the corresponding switch.

Referring back to FIG. 1, the first switch S1 and the second switch S2 have to be designed such that they are able to block only the relatively low driving voltage U_{drive} from the power source 102 which may be in the range of up to a few tens of volts, for example 8V or 12V. The upper limit for the driving voltage U_{drive} may be given by the maximum permissible voltage of the accumulation dielectric. The load transistor T1 on the other hand has to have a significantly higher blocking voltage which may for example lie in the range from a few hundreds of volts, for example 300V or 500V, to about 1000V or more. The first switch S1 may provide unidirectional blocking capability with respect to its terminals, since the voltage at the first capacitance C1 is lower or at the most equal to the driving voltage U_{drive}. In other words, the first switch S1 may provide unipolar blocking capability as the voltage applied to the first switch S1 will maintain its polarity during proper operation of the driving circuit 100 according to various embodiments. The first switch S1 may therefore be configured as a low voltage MOSFET (metal-oxide-semiconductor field effect transistor). In cases where the driving voltage U_{drive} may fall below its nominal value, for example when the driving circuit 100 according to various embodiments is powered down or disconnected from the power grid, the first capacitance C1 may be discharged through the body diode of the first switch S1, if it is implemented as a MOSFET.

The second switch S2 needs to be designed such that it provides bidirectional blocking capability, since the voltage applied to the second switch S2, i.e. the potential difference between the first capacitance C1 and the second capacitance C2 is alternating after every time the second switch S2 has been closed and opened again, as the potential of the first capacitance C1 and the second capacitance C2 alternates between a higher and a lower potential after every time the second switch S2 has been closed and opened again.

In FIG. 2 a driving circuit for a transistor 200 according to various embodiments is shown. The driving circuit 200 according to various embodiments is very similar to the driving circuit 100 shown in FIG. 1, hence the same reference numbers will be used for the same components. The circuit shown in FIG. 2 may be seen to provide a more detailed illustration of one possible implementation of the first switch S1 and the second switch S2 of driving circuit 100 according to various embodiments shown in FIG. 1. In this exemplary embodiment, the first switch S1 is implemented as an enhancement-type n-channel MOSFET (NMOSFET) with its drain connected to the power source 102 and its source connected to one terminal of the second switch S2 and one side of the first capacitance C1. As already mentioned above, the potential at the drain of the first switch S1 corresponds to the potential provided by the power source 102 and is in practice always larger than (or equal to at the most) the potential at the source of the first switch S1. The second switch S2 includes a first transistor 204 and a second transistor 206. In this exemplary embodiment both transistors included in the second switch S2 are implemented as enhancement-type n-channel MOSFETs with a common source which may be helpful in reducing power losses and/or efforts for control. The drain of the first transistor 204 is coupled to the one side of the first capacitance C1 and to the first switch S1 and the drain of the second transistor 206 is coupled to the inductance 106. By implementing the second switch S2 by two MOSFETs, a bidirectional blocking capability is provided. If the potential at the first capacitance C1 is higher than the potential at the second capacitance C2, the first transistor 204 may provide blocking. In the opposite case, the second transistor 206 may provide blocking capability. The load transistor T1, as in the case of the driving circuit for a transistor 100 shown in FIG. 1, may be an EGFET or a TEDFET with its gate region and drift control regions coupled parallel to one another. In an alternative embodiment (not shown) the gate region and the at least one drift control region may also be driven by different, for example synchronized signals. The gates of all three MOSFETs are coupled to a controller 202. The controller 202 is configured to switch on and switch off the respective transistors by providing suitable gate voltages. In the exemplary implementation of the driving circuit for a transistor 200 according to various embodiments shown in FIG. 2, the enhancement-type n-channel MOSFETS require a gate voltage which is higher than the driving voltage U_{drive} provided by the power source 102 in order to be fully activated, i.e. when the driving voltage U_{drive} (from the power source 102 or the first capacitance C1) is to be provided to the control region of the load transistor T1 with as little voltage drop as possible. Therefore the controller 202, which may draw its operation power from the power source 102, needs to be configured such that it can provide voltages which are larger than the driving voltage U_{drive}. For example, the controller 202 may include means, for example a charge pump, to convert the driving voltage U_{drive} into a higher (in the case of NMOSFETS) voltage or a lower voltage (in the case of p-channel MOSFETS (PMOSFETS)) which may then be used to drive the MOSFETS of the first switch S1 and the second switch S2. Alternatively, enhancement-type PMOSFETS may be used instead in order to avoid this circumstance.

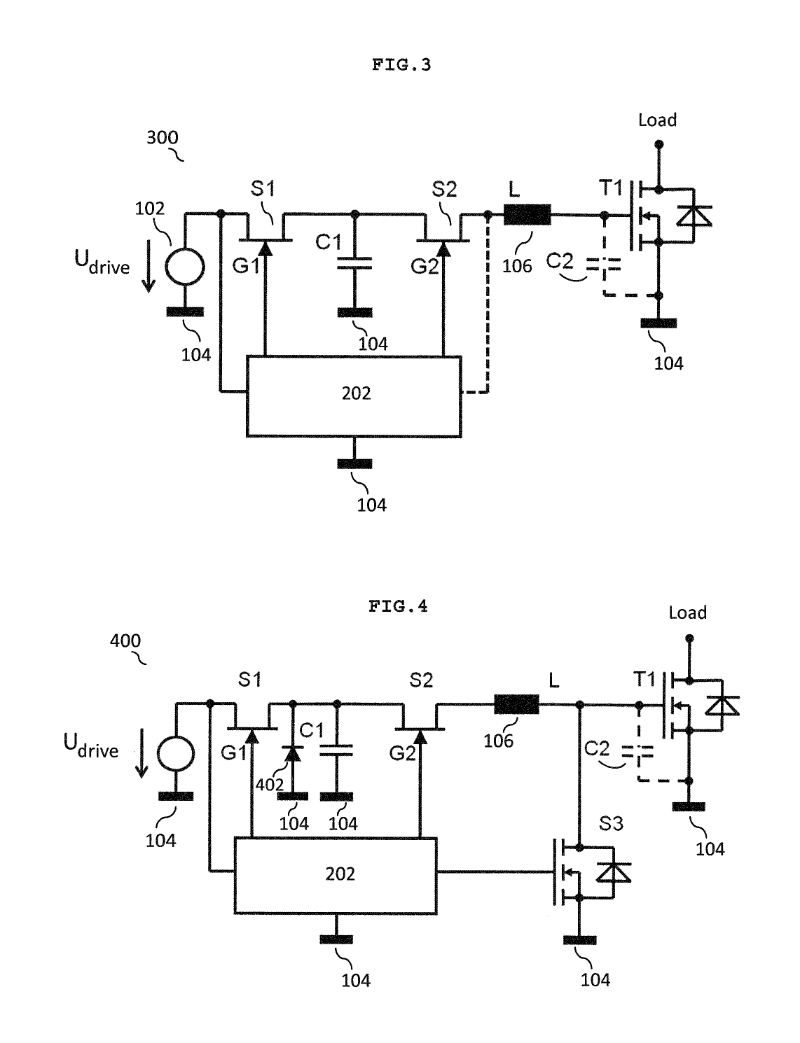

In FIG. 2 in addition to the first capacitance C1 and the second capacitance C2 a further capacitance 208 is provided, which may be provided externally, i.e. it may not be monolithically integrated in the load transistor T1. Depending on the particular application, the further capacitance 208 may be also integrated into the load transistor T1 or into its package, such that the necessity to provide an external component may be avoided. One side or terminal of the further capacitance 208 may be coupled to the electrical path between the inductance 106 and the control region (for example the gate region and the drift control region(s)) of the transistor T1, the other side or terminal of the further capacitance 208 may be coupled to the reference potential 104, for example the ground potential. In other words, the further capacitance 208 may be coupled in parallel to the second capacitance C2. The value of the capacitance of the further capacitance 208 may be on the order of the value of the capacitance of the second capacitance C2 in the fully activated state of the load transistor T1. The second capacitance C2 may be seen as a dynamic capacitance with a variable capacitance value. When the transistor T1 is in an non-conducting state, its capacitance value is smaller and increases during the switching-on process of the transistor T1 to reach its maximal value once the transistor T1 is fully activated, i.e. in a fully conducting state. The further capacitance 208 may enhance the energy transfer from the inductance 106 to the second capacitance C2 by acting as a buffer for the charges flowing towards the control region of the transistor T1 in the beginning of the charging phase, when the second capacitance C2 may have a reduced capacitance value. The further capacitance 208 may prevent the voltage of the second capacitance C2 from increasing and reaching too fast the voltage of the first capacitance C1 as this would lead to a premature slowing down of the transfer of charges from the first capacitance C1 to the control region(s) of the load transistor T1. The further capacitance 208 may be seen to function as a start-up booster in the sense that it helps draw more energy from the magnetized inductance 106 during the switch-on phase of the load transistor T1. The provision of the further capacitance 208 is independent of the manner in which the first switch S1 and the second switch S2 are implemented and may be therefore be also provided in the driving circuit for a transistor 100 shown in FIG. 1 or any other embodiment thereof, for example in the ones which will be described in the following with reference to FIG. 3 and FIG. 4.

In FIG. 3 a further implementation of the driving circuit 300 for a transistor according to various embodiments is shown. It is based on the implementation shown in FIG. 2 such that the same reference numbers are used for the same elements/components.

The main difference between the implementation shown in FIG. 2 and the implementation shown in FIG. 3 is that the first switch S1 and the second switch S2 in the implementation of the driving circuit 300 according to various embodiments shown in FIG. 3 each includes only one transistor, in this case an n-channel JFET. The implementation shown in FIG. 3 may be seen to be symmetric, as each of the JFETs used as a switch may provide bidirectional or bipolar blocking capability, i.e. blocking capability irrespective of the polarity of the voltage applied between its drain and source. Each of the JFETs in the implementation of the driving circuit 300 for a transistor in FIG. 3 may be configured such that it allows at least the driving voltage U_{drive} provided by the power source 102 as a tolerable pinch-off voltage between its gate and source or drain, respectively.

If a voltage is applied to the gate G1 of the first JFET S1, such that the difference between that gate voltage and the driving voltage U_{drive} is less than the pinch-off voltage, the first JFET S1 will become conducting and the first capacitance C1 may be charged by the power source 102. When the first JFET S1 is to be rendered non-conducting, the voltage provided to its gate G1 has to be lowered, for example to the reference potential 104, e.g. the ground potential. The same applies to the functionality of the second JFET S2 in the embodiment of the driving circuit 300 shown in FIG. 3. As both the first JFET S1 and the second JFET S2 are symmetric with respect to their blocking capability, they are rendered non-conducting when the potential at their gates is lowered to the reference potential, irrespective of the polarity of the voltage applied between their drains and sources. This bipolar blocking capability may be provided taking into consideration that the JFETs have to be designed for blocking voltages in the range of the driving voltage U_{drive} only, which in general may be in the range of a few tens of volts, for example between approximately 5V and approximately 20V or 30V. Alternatively, depletion-type PMOSFETS and/or NMOSFETS may be used instead of the JFETs.

It may prove advantageous for the intrinsic safety of the load transistor T1 and its fail-safe blocking of the load voltage during switching on and switching off of the load transistor T1 that the following condition with regard to the employed voltages is satisfied:

|U_{pinch-off}|<Uₘᵢₙ_{_{—}}_{controller}<U_{T1}_{_{—}}ₒₚₑᵣₐₜᵢₒₙₐₗ,

wherein U_{pinch-off} denotes the pinch-off voltage of the JFETs, Uₘᵢₙ_{_{—}}_{controller} denotes a minimum operation voltage of the controller 202 and U_{T1}_{_{—}}ₒₚₑᵣₐₜᵢₒₙₐₗ denotes the target voltage which needs to be applied to the control terminal of the transistor T1 when it is to be rendered conducting.

When the transistor T1 is to be activated, the power source 102 is switched on and the driving voltage U_{drive} is increasing. The first JFET S1 and the second JFET S2 in FIG. 3 are conducting. Therefore, the driving voltage U_{drive} is directly applied to the control terminal of the load transistor T1. Shortly thereafter the operation voltage of the controller 202 reaches Uₘᵢₙ_{_{—}}_{controller} and the controller 202 starts operating, i.e. the controller 202 is powered on. Having started operating, the controller 202 pulls both the potential applied to the gate G1 of the first JFET S1 and the potential applied to the gate G2 of the second JFET S2 to the reference potential 104, for example to the ground potential, and thus the JFETs are rendered non-conducting since the modulus of their pinch-off voltage is smaller than the operation voltage of the controller 202. In other words, the potential difference between the gates of the JFETs and their source terminals exceeds their pinch-off voltage resulting in the JFETs being rendered non-conducting. However, at this point the voltage at the control terminal of the load transistor T1 has not yet reached the target value required for switching on the load transistor T1. Therefore, the transistor T1 is not yet conducting. This procedure ensures that at no time during the process of powering on of the driving circuit 300 controlling the transistor T1 an uncontrollably high voltage is applied to the control terminal thereof. The same procedure may be also followed when the driving circuit 300 is switched off (only in reverse order). This way the load transistor T1 and/or the load connected thereto may be prevented from degradation or damage in situations, where an already high voltage is present at the load side terminal of the transistor T1 and the load transistor T1 is switched on in an uncontrolled manner due to the controller 202 not being fully operational yet.

As an alternative or in addition to the secure powering on and powering off procedure just described, the control terminal of the load transistor T1 may be connected to the reference potential during the power-on and/or power-off phase via the controller 202. This measure may provide a well-defined potential at the control terminal of the transistor T1 and reliably keep the transistor T1 in a non-conducting state in the beginning of the power-on phase and/or the end of the power-off phase thereof. According to various embodiments, the powering on phase and the powering off phase refer to the phases during which the load transistor T1 may be powered on and/or the load may be connected to the power grid and the phase in which the load transistor T1 may be powered off and/or the load may be disconnected from the power grid, respectively. Those two phases are to be distinguished from the normal switching on/off processes of the load transistor T1 once it has been powered on. For this reason, the controller 202 may have a terminal which is coupled to the electrical path between the second switch S2 and the inductance 106 which is indicated by the dashed line in FIG. 3. However, that connection node may be moved down the line towards the transistor T1 and, for example, also be connected to the electrical path between the inductance 106 and the load transistor T1. The connecting of the gate terminal of the transistor T1 to the reference potential may be controlled and performed by the controller 202 itself or may be controlled by the controller 202 and performed via an external switch (not shown in FIG. 3) which is controlled by the controller 202. The additional path (dashed line in FIG. 3) may be also provided in the embodiment of the driving circuit 200 shown in FIG. 2 as it is independent of the actual technical implementation of the first switch S1 and the second switch S2.

It is to be noted that the load transistor T1 may be replaced by any other equivalent gate-controlled device to which the secure powering on and powering off procedure may be applied, for example an insulated gate bipolar transistor (IGBT), a power MOSFET, a gate turn-off thytristor (GTO-thyristor) or a MOS-controlled thyristor (MCT).

The controller 202 may be also configured to use the terminal coupled to the electrical path between the second switch S2 and the inductance 106 (indicated by the dashed line in FIG. 3) in order to recharge the control regions of the transistor T1 to their preset values, for example when the transistor T1 is to remain switched on for a long time and leakage currents may lower the charge initially provided to its control regions which may result in a slight (but nevertheless unwanted) increase of the on-state resistance of the transistor T1.

As already mentioned, the second capacitance C2 may represent the gate capacitance and the drift control region capacitance. In order to have the possibility to accurately set the resonance frequency defining the duration of the charge transfer back and forth between the first capacitance C1 and the second capacitance C2, an additional capacitance, for example the further capacitance 208 shown in FIG. 2, may be provided in the driving circuit according to various embodiments. The additional capacitance may be used to slow down the switching characteristic (for example the switch-on process and/or the switch-of process) of the transistor T1 which may for example increase EMI compatibility of the device. The additional capacitance may be provided in the form of an external capacitance, as was already described with regard to the further capacitance 208 shown in FIG. 2. However, the additional capacitance may be (additionally or alternatively) also provided as an internal capacitance which may be monolithically integrated into the transistor T1. Adding additional capacitances which are coupled in parallel to the (inherent) second capacitance C2 may cause the capacitance characteristic (i.e. the relation between the charge and the voltage) of the second capacitance C2 to become more linear and therefore more predictable. Furthermore, by implementing additional capacitances in parallel to the second capacitance C2—if the overall capacitance formed thereby which may be provided externally (i.e. not included monolithically into the transistor T1) is larger than the capacitance of the gate region and/or the drift control region of the transistor T1—the driving circuit for a transistor according to various embodiments may be used in connection with load transistors T1 of different sizes and with different switch-on resistances without the need of individual adjustments, such as the dimensioning of the driving circuit.

The first capacitance C1 and/or the inductance 106 may be also, at least partially, monolithically integrated in the load transistor T1. Considering that the connecting paths to and from the inductance 106 are part of the load transistor T1, a partial monolithic integration in the load transistor T1 may be inherently present in the driving circuit according to various embodiments anyways. It may also prove advantageous to monolithically implement the first switch S1 and the second switch S2 into the load transistor T1. Semiconductor components such as EGFETs and TEDFETs include—due to their inherent structure—lateral and vertical isolation regions, for example lateral and vertical dielectric isolation regions. Therefore, at least one of the switches, for example at least one of the n-channel JFETs, may be fabricated during the fabrication of the load transistor T1 with only a few (additional) lithographic layers. In EGFET devices, a diode has to be provided between the end portion of the drift control region closest to the drain and the drain electrode. The anode of the diode is typically connected to the drain terminal to provide an electrical path for the leakage current (electrons) to the drain terminal in non-conducting state of the transistor. This leakage current diode may be also implemented monolithically in the semiconductor substrate of the load transistor T1.

In FIG. 4 a further implementation of the driving circuit 400 for a transistor according to various embodiments is shown. It is based on the implementation shown in FIG. 3 such that the same reference numbers are used for the same elements.

The driving circuit 400 according to various embodiments is similar to the driving circuit 300 according to various embodiments shown in FIG. 3. With regard thereto, the electrical path (indicated by the dashed line) between the output of the second switch S2 and the inductance 106 has been altered in the sense that the controller 202 is coupled to a control terminal of an third switch S3 which is coupled between the reference potential 104, for example the ground potential, and the electrical path between the inductance 106 and the control terminal of the load transistor T1. In its function, the third switch S3 is equivalent to the solution already presented and discussed with regard to FIG. 3—the controller 202 may control the third switch S3 to connect and disconnect the control terminal of the load transistor T1 to and from the reference potential 104. This electrical path to the reference potential (in either one of the two implementations, i.e. third switch S3 controlled by the controller 202 or this function being implemented in the controller 202) may be used to provide an electrical path for leakage current in the form of holes from the control terminal of the load transistor T1 in its non-conducting state (or blocking state) to the reference potential 104. As already mentioned, this path may be also used to connect the second capacitance to the reference potential 104 during the power-on phase and the power-off phase of the load transistor T1 to prevent uncontrollably high voltages at the gate terminal thereof. The connection node between the third switch S3 and the control terminal of the load transistor T1 may be moved up the line away from the transistor T1 and, for example, be instead connected to the electrical path between the inductance 106 and the second switch S2. In other words, position of the electrical path represented by the dashed line in FIG. 3 and the position of the electrical path represented by the electrical path leading through the third switch S3 in FIG. 4 may be exchanged with one another. The third switch S3 may be also monolithically integrated into the load transistor T1.

The third switch S3 shown in FIG. 4 may be switched at the same time as the second switch S2. As soon as the second switch S2 has been opened after the second capacitance C2 has been discharged such that the load transistor T1 is in a non-conducting state, the third switch S3 is closed, i.e. rendered conducting. When the load transistor T1 is in a conducting state, both the second switch S2 and the third switch S3 are opened, i.e. non-conducting. By comparison of those two situations it can be seen that the switching scheme for the third switch S3 does not correspond to a simple inversion of the switching scheme for the second switch S2. The body diode in the third switch S3 may be used to prevent the voltage at the control terminal of the load transistor to drop below the reference potential 104, for example the ground potential.

The first switch S1 and the third switch S3 may be used to set or define the potentials at the first capacitance C1 and the second capacitance C2, respectively, as well as to compensate for small deviations in the timings in the switching schemes of the switches. A build-up of disturbances due to the first switch S1 and/or the second switch S2 having been switched on or switched off for times which slightly deviate from preset values, i.e. when the first switch S1 and/or the second switch S2 have remained switched on or switched off for slightly too long or slightly too short, may be effectively prevented. The first switch S1 may be closed when the transistor T1 is in non-conducting state in order to recharge the first capacitance C1 to the driving voltage U_{drive} and, for example, thereby compensate for possible leakage currents or losses during switching of the switches which may lead to a reduced voltage on the first capacitance C1 (with respect to the driving voltage U_{drive}). The third switch S3 may be used to discharge the second capacitance C2 when the load transistor T1 is in non-conducting state and thereby create a well-defined potential, which for example may correspond to the reference potential, on the second capacitance C2 before the next switching on of the load transistor T1. In other words, too high or too low potentials on the first capacitance C1 and/or the second capacitance C2 due to the respective switches having been switched on or switched off for too short or too long times or due to leakage currents or any other possible reasons may be corrected after every switching cycle of the load transistor T1 at the latest and thereby allow for a stable and continually controllable operation of the load transistor T1.

In the embodiment of the driving circuit 400 for a transistor shown in FIG. 4 a further optional modification is shown which may be implemented in all the other embodiments shown in FIG. 1 through FIG. 3. The driving circuit for a transistor 400 according to various embodiments includes a diode 402, wherein its cathode may be coupled to the electrical path between the first switch S1 and the first capacitance C1 and its anode may be coupled to the reference potential 104, for example to the ground potential. In other words, the diode 402 maybe coupled in antiparallel arrangement with respect to the first capacitance C1 in order to provide a free-wheeling path. The diode 402 may act as a voltage limiting element in the sense that it may limit a build-up of negative voltage across the first capacitance C1 to, for example, the typical forward voltage of 0.7V (in case the diode 402 is a silicon pn-diode). This may prevent the first capacitor C1 from being damaged, as connecting some kinds of capacitors, for example electrolytic capacitors, in reverse polarity can easily damage them. Without the free-wheeling diode 402 a negative voltage may build up across the first capacitance C1 if the second switch S2 remains closed for a time which is longer than half the oscillating time period dictated by the values of the inductance 106 and the first capacitance C1. In addition, by providing the free-wheeling diode 402, the current driven by the magnetized inductance 106 charging the second capacitance C2 may decrease at a slower rate (compared to the case when the diode 402 is missing) after the point in time, when the voltage across the first capacitance C1 (which, for example, starting at the driving voltage U_{drive} has been steadily decreasing upon closing of the second switch S2) is equal to the voltage across the second capacitance C2 (which, for example, starting at the reference potential has been steadily increasing upon closing of the second switch S2).

It is to be noted that the driving circuit for a transistor may be analogously applied to other load switches, for example to a field plate transistor, wherein the field plate and the gate may have the same potential.

The driving circuit for a transistor according to various embodiments may be also used to drive a TEDFET, wherein the gate of the TEDFET may be driven in a conventional manner (for example, using a driver circuit and a gate resistance) and the drift control regions may be driven by the driving circuit for a transistor according to various embodiments as shown in FIG. 1 through FIG. 4. In such a scenario, the drift control region may be charged up to a voltage which corresponds to the breakdown voltage of the dielectric layer separating the drift control region from the drift region when the TEDFET is in conducting state. When the TEDFET is in non-conducting state, only a small remaining potential is present in the drift control region which may correspond to the source potential such that the blocking capability of the TEDFET is not reduced. The minimum switch-on resistance of a TEDFET may be reduced by approximately by a factor of ⅓ in comparison to a TEDFET with otherwise the same structure but the drift control region of which is charged in a conventional manner (i.e. in the manner outlined above in which the gate is conventionally charged). At this point it may be mentioned that the control current which needs to be provided to the control regions of a EGFET during its switching process may have current peaks of about 100 A which is comparable to the magnitude of the load currents which are conducted by the EGFET when it is switched on. By using the driving circuit for a transistor according to various embodiments, this high control current may be stored in the capacitance acting as a charge buffer and thus does not have to be provided from the power source in every switching cycle which may at least advantageous with respect to the overall power consumption of the driving circuit for a transistor according to various embodiments.

According to various further embodiments of the driving circuit for a transistor the magnitude of the voltage applied to the control terminal of the driving transistor T1 in conducting state may be modulated by adjusting the driving voltage U_{drive}. In such a scheme the controller 202 may be connected to a fixed or constant supply voltage instead of being connected to the variable or fluctuating driving voltage U_{drive} (as indicated in FIG. 2 through FIG. 4, the controller 202 may draw its operation voltage from the power source 102 as it is connected to the output thereof). In other words, the controller 202 may be provided with a fixed operation voltage which may and be used to provide a driving voltage of a variable magnitude to the control terminal of the load transistor T1, for example to a gate region and/or the drift control region of a TEDFET.

It is to be noted that more than one load transistor T1, for example 2, 5, 12 or 24 or any other suitable amount of load transistors may be coupled in parallel and driven by a single driving circuit for a transistor according to various embodiments. The control terminals of the multiple load transistors coupled in parallel may be all coupled in parallel to the inductance 106 and they may all share one further capacitance 208 (see FIG. 2). The sources and the drains of the multiple load transistors coupled in parallel may be coupled to one another or may be formed as one common source region and/or one common drain region, respectively.

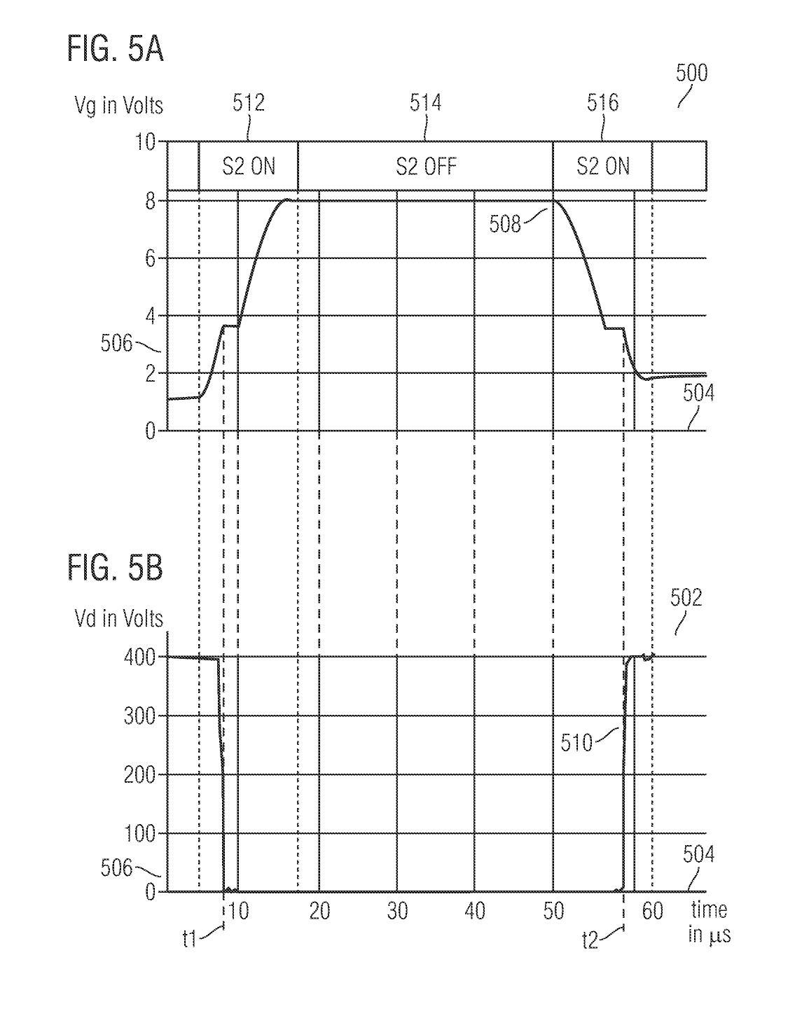

FIGS. 5A and 5B illustrate an exemplary control voltage and an exemplary drain voltage of a load transistor T1 during an exemplary switching process of the load transistor T1 in the driving circuit for a transistor according to various embodiments. In diagram 500 in FIG. 5A the control voltage 508 which may be applied to the gate region and/or the drift control regions of the load transistor T1 is shown, the y-axis denoting the magnitude of the gate voltage 508 in volts. In diagram 502 in FIG. 5B the drain voltage 510 is shown, the y-axis 506 denoting the magnitude of the drain voltage 508 in volts. Both diagrams share the same x-axis 504 which denotes time in microseconds.

Three distinct phases are marked in the diagrams: a first phase 512, a second phase 514 and a third phase 516. The first phase 512, during which the second switch S2 is closed, may correspond to the switch-on phase of the load transistor T1. During the first phase 512, charges from the first capacitance C1 may be transferred to the control region(s) of the load transistor T1 (for example to the gate region and/or the drift control regions thereof). However, it can be seen that the resistance of the load transistor T1 does not drop significantly until the gate voltage 508 has reached approximately 3.8V (exemplary value according to one embodiment) at a time t1. Up to the time t1, the gate to source capacitance is charged and the transistor T1 remains switched off. Once the gate to source capacitance is charged at approximately the time t1, the drain to source resistance drops to a negligible value while the Miller capacitance is discharged. The discharge of the Miller capacitance is reflected in the plateau in the control voltage 508 starting at the time t1 and ending shortly thereafter. Roughly 4 microseconds after the second switch S2 has been closed, the resistance of the path between source and drain of the load transistor T1 is reduced to a negligible value. This situation is equivalent to the load transistor T1 being fully switched on (i.e. conducting). The drop in the resistance of the load transistor T1 is directly reflected in the drain voltage 510 dropping from 400V to a negligible value of approximately 0V around the time t1 in the first phase 512. Shortly after the gate voltage 508 has reached its target value of 8V (exemplary value according to one embodiment), the second switch S2 is switched off. This event marks the beginning of the second phase 514 during which the second switch S2 remains switched off (i.e. non-conducting) and during which the load transistor T1 remains switched on. At the end of the second phase 514 the second switch S2 is closed again such that the control regions of the load transistor T1 may be discharged into the first capacitance C1. However, in analogy to the first phase 512, the load transistor is not switched off until the gate voltage has dropped to approximately 3.8V at a time t2 in the third phase 516. At the end of the third phase 516 the second switch S2 may be opened again such that the load transistor T1 remains in off-state. In addition, at the end of the third phase 516 the third switch S3 may be closed (in case the third switch S3 is provided in the driving circuit for a transistor according to various embodiments) in order to fully discharge the second capacitance C2. This may guarantee that the potential of the second capacitance C2 is well-defined and equal to the reference potential 104, e.g. the ground potential. At the same time the first switch S1 may be closed in order to ensure that the voltage across the first capacitance C1 is equal to the driving voltage U_{drive}.

In general, with the driving circuit for a transistor according to various embodiments switching frequencies from a few Hertz to a few tens of kilohertz, for example 20 kHz may be achieved. According to various embodiments of the driving circuit for a transistor, the first capacitance C1 may have capacitance values in the range of a few tens of nanofarad, for example 20 nF. The inductance 106 may have inductance values in the range between a few microhenry, for example 10 μH, and a few tens of milihenry, for example 50 mH, or even a few hundreds of milihenry, for example 100 mH. The inductance value may be considerably larger than the overall parasitic inductance of the driving circuit for a transistor.

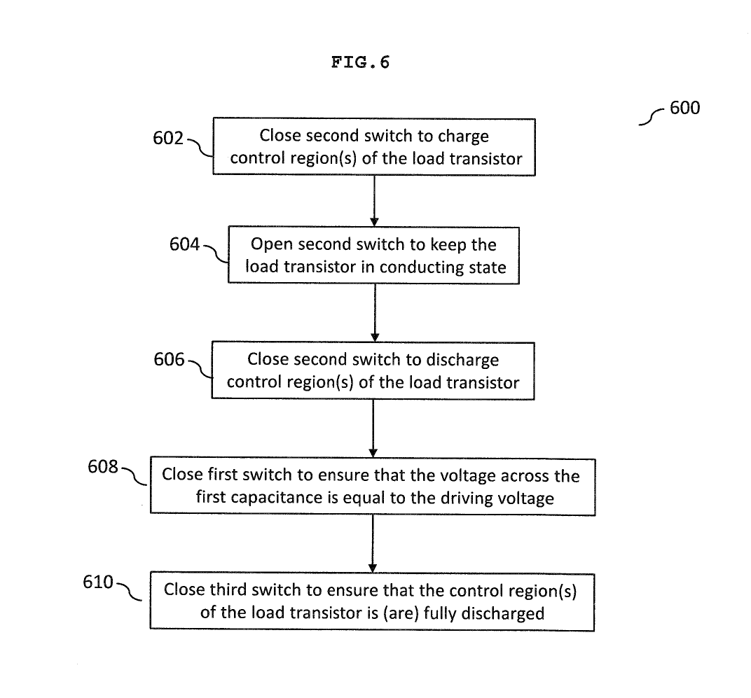

In FIG. 6 an exemplary switching method 600 which may be used with the driving circuit according to various embodiments is illustrated. The presented switching method 600 is based on the assumption that the load transistor T1 is switched off and that the first capacitance C1 functioning as a charge reservoir for the control regions of the load transistor T1 is fully charged, i.e. the voltage across the first capacitance C1 is equal to the driving voltage U_{drive} provided by the power source 102. Also, in case the third switch S3 (or an analogous functionality provided in the controller, as depicted in FIG. 3) is provided, it is assumed that shortly before or at the latest at the time when the load transistor T1 is to be switched on, the switch S3 is opened such that the control terminal of the load transistor T1 is disconnected from the reference potential 104.

In a first step 602, the second switch S2 may be closed in order to charge the control region(s) (such as the gate region and/or the drift control region(s)) of the load transistor T1. During the switch-on process of the load transistor T1, the second switch S2 may remain closed for a period of time which is approximately equal to half the oscillating time period of the oscillator circuit formed by the inductance 106 and the first capacitance C1.

After the load transistor T1 has been switched on, the second switch S2 may be opened and kept open in a second step 604 in order to keep the load transistor T1 switched on (i.e. in a conducting state). During this step the gate of the load transistor T1 may be optionally connected to a driving voltage for compensating leakage currents, mainly during long turn-on times, for example via the electrical path between the second switch S2 and the inductance 106 which is indicated by the dashed line in FIG. 3.

In a third step 606, the second switch S2 may be closed in order to discharge the control region(s) of the load transistor. The third step 606 may be seen to include the reverse process of the first step 602.

In a fourth step 608, after the load transistor T1 has been switched off in the previous step, the first switch S1 may be closed to ensure that the voltage across the first capacitance C1 is equal to the driving voltage driving voltage U_{drive}. The controller 202 may be configured to sample the voltage across the first capacitance C1 in order to assess the time the first switch S1 needs to be closed for such that the charging time is sufficient for the first capacitance C1 to reach its target voltage (which is equal to the driving voltage U_{drive}). However, at this step the first switch S1 may be closed for a standard period of time which is sufficient for the first capacitance C1 to reach its target value in a statistically significant amount of cases.

In a fifth step 610, the third switch S3 (if provided in the driving circuit for a transistor according to various embodiments) may be closed to ensure that the control region(s) of the load transistor T1 is (are) fully discharged.

After the process according to the fifth step 610 has been performed, the load transistor T1 is in a state it was in prior to performing the switching method 600 according to various embodiments. It is to be noted that the fourth step 608 and the fifth step 610 may be exchanged with one another or take place at the same time. In other words, as long as the second switch S2 is closed during off-state of the load transistor T1, it is irrelevant which of the other switches (i.e. the first switch S1 and the third switch S3) is switched on first and/or switched off first. However, as mentioned above, both the first switch S1 and the third switch S2 may need to be opened before the next switching process as depicted by the switching method 600 according to various embodiments is initiated.

In accordance with various embodiments, a driving circuit for a transistor is provided. The driving circuit may include: a transistor including a control terminal; a capacitance; a first switch and a power source, wherein the first switch may be coupled between the power source and a first terminal of the capacitance; a second switch and an inductance which may be coupled in series between the first terminal of the capacitance and the control terminal of the transistor.

According to various further embodiments of the driving circuit for a transistor the control terminal of the transistor may be coupled to a gate of the transistor.

According to various further embodiments of the driving circuit for a transistor the control terminal of the transistor may be coupled to a drift control region of the transistor.

According to various further embodiments of the driving circuit for a transistor a gate and a drift control region of the transistor may be coupled in parallel to the control terminal of the transistor.

According to various further embodiments of the driving circuit for a transistor the gate and the drift control region of the transistor may be formed as one region.

According to various further embodiments of the driving circuit for a transistor the transistor may include an internal capacitance which is formed by the gate and at least one drift control region of the transistor.

According to various further embodiments of the driving circuit for a transistor the inductance and the capacitance may define an oscillating time period.

According to various further embodiments of the driving circuit for a transistor the first switch may include a first transistor.

According to various further embodiments of the driving circuit for a transistor the first transistor may be configured to be capable of blocking voltages of one polarity.

According to various further embodiments of the driving circuit for a transistor the first transistor may be configured as a MOSFET or as a JFET.

According to various further embodiments of the driving circuit for a transistor the second switch may include at least one second transistor.

According to various further embodiments of the driving circuit for a transistor the second switch may be configured to be capable of blocking voltages of both polarities.

According to various further embodiments of the driving circuit for a transistor the second switch may be configured as a JFET.

According to various further embodiments of the driving circuit for a transistor the second switch may include two MOSFETs coupled in series, wherein the drains or the sources of the MOSFETs coupled to one another.

According to various further embodiments of the driving circuit for a transistor the first switch may include a first transistor and the second switch may include at least one second transistor and the blocking voltage of the first transistor and the at least one second transistor may be at least equal to or larger than a voltage supplied by the power source.

According to various further embodiments of the driving circuit for a transistor the first switch may include a first transistor and the second switch may include at least one second transistor and the transistor, the first transistor and the at least one second transistor may be monolithically integrated in one substrate.

According to various further embodiments of the driving circuit for a transistor the transistor and at least a part of the inductance may be monolithically integrated in one substrate.

According to various further embodiments of the driving circuit for a transistor the transistor and at least a part of the capacitance may be monolithically integrated in one substrate.

According to various further embodiments, the driving circuit for a transistor may further include a controller configured to control the operation of the first switch and the second switch.

According to various further embodiments of the driving circuit for a transistor the controller may be configured to close the first switch and the second switch when the transistor is to be switched on and the capacitance is not fully charged to a preset voltage.

According to various further embodiments of the driving circuit for a transistor the controller may be configured to close the second switch when the transistor is to be switched on and the capacitance is substantially fully charged to a preset value.

According to various further embodiments of the driving circuit for a transistor the controller may be configured to close the first switch during intervals in which the second switch remains opened.

According to various further embodiments of the driving circuit for a transistor the controller may be configured to close the second switch for a period of time which corresponds to half the oscillating time period defined by the inductance and the capacitance when the transistor is to be switched on.

According to various further embodiments of the driving circuit for a transistor the controller may be configured to close the second switch for a period of time which corresponds to half the oscillating time period defined by the inductance and the capacitance when the transistor is to be switched off.

According to various further embodiments of the driving circuit for a transistor the control terminal of the transistor may be controllably coupled to a reference potential and the controller may be configured to establish an electrical connection between the control terminal of the transistor to the reference potential when the transistor is in non-conducting state.

According to various further embodiments, the driving circuit for a transistor may further include an auxiliary capacitance which may be coupled in parallel to the internal capacitance of the transistor.

According to various further embodiments of the driving circuit for a transistor the capacitance value of the auxiliary capacitance may be at least equal to the capacitance value of the internal capacitance.

According to various further embodiments, the transistor may be replaced by a gate-controlled device such as an insulated gate bipolar transistor (IGBT), a power MOSFET, a gate turn-off thyristor (GTO-thyristor) or a MOS-controlled thyristor (MCT).

According to various further embodiments, the driving circuit for a transistor may further include a diode coupled in parallel to the capacitance, wherein the cathode of the diode may be coupled to the electrical path between the first switch and the second switch and the anode of the diode may be coupled to a reference potential.

In accordance with various further embodiments a control circuit for a transistor is provided. The control circuit may include: a load transistor having a control terminal, which may include a gate region and/or at least one drift control region; a capacitor; a first control transistor; a power source, wherein the first control transistor is coupled between the power source and a first terminal of the capacitor; a second control transistor; an inductor, wherein the second control transistor and the inductor are coupled in series between the first terminal of the capacitor and the control terminal of the load transistor.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A driving circuit for a transistor, comprising:
a transistor comprising a control terminal;
a capacitance;
a first switch and a power source, wherein the first switch is coupled between the power source and a first terminal of the capacitance;
a second switch and an inductance which are coupled in series between the first terminal of the capacitance and the control terminal of the transistor.

2. Driving circuit for a transistor of claim 1,
wherein the control terminal of the transistor is coupled to a gate of the transistor.

3. Driving circuit for a transistor of claim 1,
wherein the control terminal of the transistor is coupled to at least one drift control region of the transistor.

4. Driving circuit for a transistor of claim 2,
wherein the gate and at least one drift control region of the transistor are coupled in parallel to the control terminal of the transistor.

5. Driving circuit for a transistor of claim 2,
wherein the transistor comprises an internal capacitance which is formed by the gate and at least one drift control region of the transistor.

6. Driving circuit for a transistor of claim 1,
wherein the inductance and the capacitance define an oscillating time period.

7. Driving circuit for a transistor of claim 1,
wherein the first switch comprises a first transistor.

8. Driving circuit for a transistor of claim 7,
wherein the first transistor is configured to be capable of blocking voltages of one polarity.

9. Driving circuit for a transistor of claim 1,
wherein the second switch comprises at least one second transistor.

10. Driving circuit for a transistor of claim 9,
wherein the second switch is configured to be capable of blocking voltages of both polarities.

11. Driving circuit for a transistor of claim 9,
wherein the second switch is configured as a JFET.

12. Driving circuit for a transistor of claim 9,
wherein the second switch comprises two MOSFETs coupled in series, wherein the drains or the sources of the MOSFETs coupled to one another.

13. Driving circuit for a transistor of claim 1,
wherein the first switch comprises a first transistor and the second switch comprises at least one second transistor; and
wherein the blocking voltage of the first transistor and the at least one second transistor is at least equal to or larger than a voltage supplied by the power source.

14. Driving circuit for a transistor of claim 1,
wherein the first switch comprises a first transistor and the second switch comprises at least one second transistor; and
wherein the transistor, the first transistor and the at least one second transistor are monolithically integrated in one substrate.

15. Driving circuit for a transistor of claim 1, further comprising:
a controller configured to control the operation of the first switch and the second switch.

16. Driving circuit for a transistor of claim 15,
wherein the controller is configured to close the first switch and the second switch when the transistor is to be switched on and the capacitance is not fully charged to a preset value.

17. Driving circuit for a transistor of claim 15,
wherein the controller is configured to close the second switch when the transistor is to be switched on and the capacitance is substantially fully charged to a preset value.

18. Driving circuit for a transistor of claim 15,
wherein the controller is configured to close the first switch during intervals in which the second switch remains opened.

19. Driving circuit for a transistor of claim 15,
wherein the controller is configured to close the second switch for a period of time which corresponds to half the oscillating time period defined by the inductance and the capacitance when the transistor is to be switched on.

20. Driving circuit for a transistor of claim 15,
wherein the controller is configured to close the second switch for a period of time which corresponds to half the oscillating time period defined by the inductance and the capacitance when the transistor is to be switched off.

21. Driving circuit for a transistor of claim 15,
wherein the control terminal of the transistor is controllably coupled to a reference potential; and
wherein the controller is configured to establish an electrical connection between the control terminal of the transistor to the reference potential when the transistor is in non-conducting state.

22. Driving circuit for a transistor of claim 5, further comprising:
an auxiliary capacitance which is coupled in parallel to the internal capacitance of the transistor.

23. Driving circuit for a transistor of claim 22,
wherein the capacitance value of the auxiliary capacitance is at least equal to the capacitance value of the internal capacitance.

24. Driving circuit for a transistor of claim 1, further comprising:
a diode coupled in parallel to the capacitance, wherein the cathode of the diode is coupled to the electrical path between the first switch and the second switch and the anode of the diode is coupled to a reference potential.

25. A control circuit for a transistor, comprising:
a load transistor comprising a control terminal, which may comprise a gate region and/or at least one drift control region;
a capacitor;
a first control transistor;
a power source, wherein the first control transistor is coupled between the power source and a first terminal of the capacitor;
a second control transistor;
an inductor, wherein the second control transistor and the inductor are coupled in series between the first terminal of the capacitor and the control terminal of the load transistor.
